(19) United States
(12) Patent Application Publication
(10) Pub. No.: US 2015/0236022 A1
(43) Pub. Date: Aug. 20, 2015

(54) SEMICONDUCTOR DEVICE AND MANUFACTURING METHOD THEREOF

(71) Applicants: Kiyonori OYU, Tokyo (JP); PS4 LUXCO S.A.R.L., Luxembourg (LU)

(72) Inventor: Kiyonori Oyu, Tokyo (JP)

(73) Assignee: PS4 LUXCO S.A.R.L., Luxembourg (LU)

(21) Appl. No.: 14/429,758

(22) PCT Filed: Sep. 20, 2013
(86) PCT No.: PCT/JP2013/005570

§ 371 Date: Mar. 19, 2015

(30) Foreign Application Priority Data
Sep. 26, 2012 (JP) 2012-212526

(51) Int. Cl. H01L 27/108

(52) U.S. Cl. CPC H01L 27/10823; H01L 27/10808; H01L 27/10876; H01L 27/10855

(57) ABSTRACT

Disclosed herein is a semiconductor device that includes: a semiconductor substrate; a well of a first conductive type that is formed in the semiconductor substrate; an element isolation region embedded in the semiconductor substrate so as to define an active region of the well; first and second gate electrodes each including a side surface and a bottom surface that are covered with the well such that the first and second gate electrodes are formed to traverse the active region, and a peak depth of the well corresponding to the active region is equal to or shallower than a peak depth of the well corresponding to the element isolation region.

### BACKGROUND

1. Field of the Invention

The present invention relates to a semiconductor device and a manufacturing method thereof, and more particularly relates to a semiconductor device including a semi-conductor substrate having a p-type well arranged thereon and a manufacturing method of such a semiconductor device.

2. Description of Related Art

In a semiconductor device such as a DRAM (Dynamic Random Access Memory), a plurality of active regions are defined by an element isolation region provided on a surface of a silicon substrate (an STI (Shallow Trench Isolation) method). In a memory cell region, two memory cells are arranged in each of the active regions. Japanese Patent Application Laid-open No. 2012-134439 discloses an example of such an active region.

Each of the memory cells is constituted by a cell transistor and a cell capacitor. While various shapes are employed for the cell transistor, in one of these shapes of the cell transistor, a gate electrode (a word line) is embedded in the silicon substrate and a p-type well provided on a surface of the silicon substrate works as a channel layer.

In the conventional semiconductor device described above, when a first memory cell of two memory cells corresponding to one active region stores therein high level data, if writing of low level data in a second memory cell is repeated many times, the stored data (of a high level) of the first memory cell may be broken and the data is changed to a low level.

This phenomenon is referred to as “disturbance defect”, which is caused by an electron generated by switching on and off the cell transistor of the second memory cell and reaching a cell capacitor of the first memory cell. In the invention of Japanese Patent Application Laid-Open No. 2012-134439, an impurity diffusion layer, which is deeper than that those in typical cases, is provided between the two cell transistors, by which transfer of electrons is blocked, thereby suppressing generation of the disturbance defect.

### SUMMARY

In one embodiment, there is provided a semiconductor device that includes: a semiconductor substrate having a main surface; a well of a first conductive type formed in the semiconductor substrate; an element isolation region embedded in the semiconductor substrate so as to define an active region of the semiconductor substrate; first and second gate electrodes each embedded in the semiconductor substrate with an intervention of a gate insulation film such that the first and second gate electrodes are formed to traverse the active region, each of the first and second gate electrodes having a top surface that is lower in position than the main surface of the semiconductor substrate; a first impurity diffusion layer of a second conductive type that is formed between the first gate electrode and the second gate electrode in the active region, the second conductive type being different from the first conductive type; and a second impurity diffusion layer of the second conductive type that is formed between the first gate electrode and the element isolation region in the active region, and a peak depth of the well corresponding to the active region is equal to or shallower than a peak depth of the well corresponding to the element isolation region.

In another embodiment, there is provided a semiconductor device that includes: a semiconductor substrate having a main surface; a well of a first conductive type that is formed in the semiconductor substrate; an element isolation region embedded in the semiconductor substrate so as to define an active region of the well; first and second gate electrodes each including a top surface, a side surface and a bottom surface, the side and bottom surfaces of each of the first and second gate electrodes being covered with the well such that the first and second gate electrodes are formed to traverse the active region, the top surface of each of the first and second gate electrodes being lower in position than the main surface of the semiconductor substrate, and a peak depth of the well corresponding to the active region is equal to or shallower than a peak depth of the well corresponding to the element isolation region.

In still another embodiment, there is provided manufacturing method of a semiconductor device that includes: etching a semiconductor substrate to form an element isolation trench; filling the element isolation trench with an insulation film to form an element isolation region that defines an active region in the semiconductor substrate; implanting an impurity into the semiconductor substrate to form a well of a first conductive type such that a peak depth of the well corresponding to the active region is equal to or shallower than a peak depth of the well corresponding to the element isolation region; forming first and second gate electrode trenches so as to stride across the active region; and embedding a conductive material in each of the first and second gate electrode trenches, the conductive material having an upper surface that is lower than an uppermost surface of the semiconductor substrate.

In still another embodiment, there is provided manufacturing method of a semiconductor device that includes: etching a semiconductor substrate to form an element isolation trench; filling the element isolation trench with an insulation film to form an element isolation region that defines a plurality of active regions of the semiconductor substrate, the active regions being arranged in a first direction; implanting an impurity into the semiconductor substrate to form a well of a first conductive type such that a peak depth of the well corresponding to the active regions is equal to or shallower than a peak depth of the well corresponding to the element isolation region; and forming first and second embedded gate electrodes that are embedded in the semiconductor substrate, the first and second embedded gate electrodes extending in the first direction so as to stride across the active regions, the first and second embedded gate electrodes having an upper surface that is lower than an uppermost surface of the semiconductor substrate.

According to the present invention, a potential distribution in a depletion layer generated at a junction portion of a well of a first conductive type and a second impurity diffusion layer of a second conductive type is spread toward a lower side (a direction of separating from a surface of a semiconductor substrate) particularly near an element isolation region, and thus an electron generated by switching on and off a first gate electrode is likely to be trapped by an interface state between the element isolation region and the well. Therefore, a probability that the electron reaches the second impurity diffusion layer is decreased, thereby suppressing generation of a disturbance defect.

### BRIEF DESCRIPTION OF DRAWINGS

FIG. 1 is a plan view of a semiconductor device according to a preferred embodiment of the present invention;

FIG. 2 is a cross-sectional view of the semiconductor device corresponding to a line A-A shown in FIG. 1;

FIGS. 3 to 6 are cross-sectional views of a semiconductor device according to a prototype example of the present invention;

FIGS. 7 and 8 are cross-sectional views of the semiconductor device according to the preferred embodiment;

FIGS. 9 to 11 show manufacturing processes of the semiconductor device according to the preferred embodiment;

FIG. 12 shows manufacturing processes of a semiconductor device according to a first modification of the preferred embodiment; and

FIGS. 13 to 15 show manufacturing processes of a semiconductor device according to a second modification of the preferred embodiment.

### DESCRIPTION OF EMBODIMENTS

Preferred embodiments of the present invention will be explained below in detail with reference to the accompanying drawings. In the following descriptions, a structure of a semiconductor device 1 according to an embodiment of the present invention is explained first, and then a characteristic of a well 3, which is related to the subject matter of the present invention, is explained in detail with reference to a prototype example. Thereafter, a manufacturing method of the semiconductor device 1 including the well 3 is explained in detail.

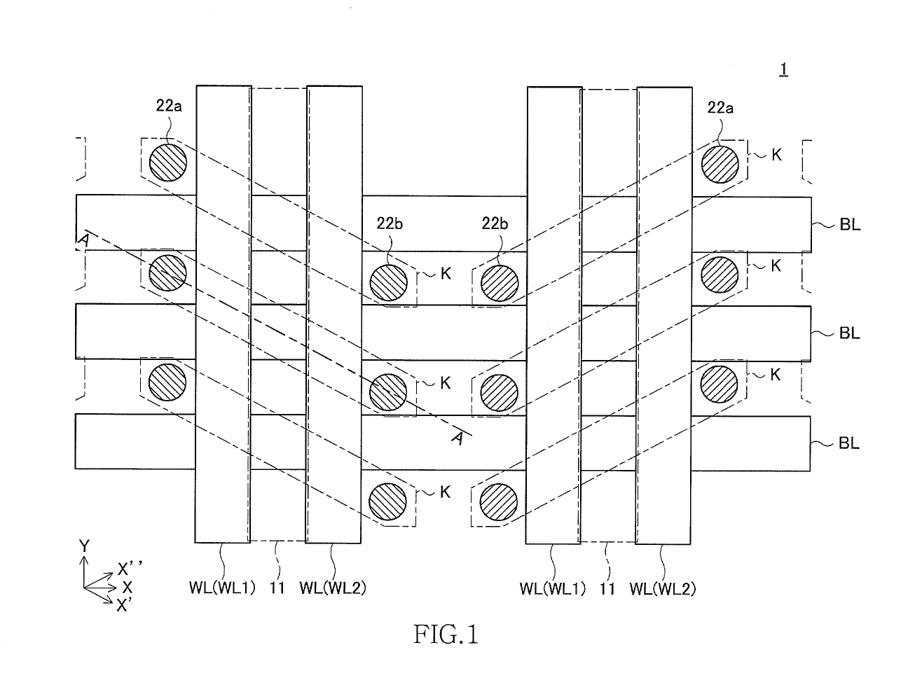

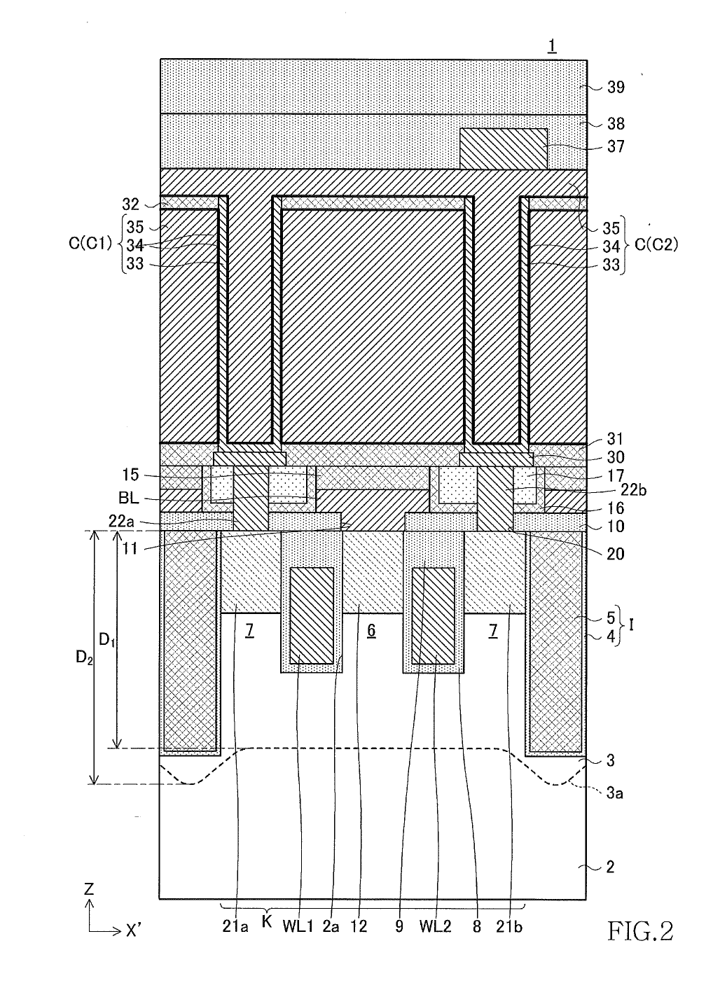

Referring now to FIGS. 1 and 2, the semiconductor device 1 is a DRAM, which includes a semiconductor substrate 2 (a silicon substrate) as shown in FIG. 2. On a surface of the semiconductor substrate 2, as shown in FIG. 1, a plurality of word lines WL extending in a Y direction (first direction) and a plurality of bit lines BL extending in an X direction perpendicular to the Y direction are arranged. Although only four word lines WL and three bit lines BL are shown in FIG. 1, in practice, a larger number of word lines WL and bit lines BL are arranged.

A silicon oxide film 4 and a silicon nitride film 5 that constitute an element isolation region I are embedded in the surface of the semiconductor substrate 2, and a plurality of active regions K are defined in a matrix form by the element isolation region I on the surface of the semiconductor substrate 2. Each of the active regions K has an elongated planar shape in an X′ direction inclined with respect to the X direction (or an X″ direction that is line-symmetric to the X′ direction with respect to an X axis). As viewed from the Y direction, each of the active regions K and the element isolation region I are alternately arranged with the same interval and the same pitch. Furthermore, the active regions K having the elongated planar shape in the X′ direction and the active regions K having the elongated planar shape in the X″ direction are, as shown in FIG. 1, alternately arranged along the X direction. Although the following explanations focus on the active regions K having an elongated planar shape in the X′ direction, the same explanation can also be applied to the active regions K having the elongated planar shape in the X″ direction.

The p-type well 3 is provided on the surface of the semiconductor substrate 2. The well 3 is formed by implanting an impurity such as Boron in the surface of the semiconductor substrate 2. A dashed line 3a shown in FIG. 2 indicates a line (a peak line) where the impurity density of the well 3 has a peak value. As shown in FIG. 2, as a distance (a peak depth) D₁ between the peak line 3a and the surface of the semiconductor substrate 2 in the active region K and a peak depth D₂ in the element isolation region I are compared, D₁?D₂ is satisfied in the present embodiment. This point is the main characteristic of the present invention, and it is explained later in detail.

Each of the active regions K includes, as shown in FIG. 1, two word lines WL (word lines WL1 and WL2) and one bit line BL, and a memory cell constituted by a cell transistor and a cell capacitor C is provided for each of the word lines WL. Each of the word lines WL constitutes a gate electrode of the corresponding cell transistor.

As shown in FIG. 2, each of the word lines WL is constituted by an embedded conductive material embedded in the surface of the semiconductor substrate 2 via a gate insulation film 8. Specifically, on the surface of the semiconductor substrate 2, a gate electrode trench 2a is provided for each of the word lines WL. The gate electrode trench 2a is formed to pass through the active regions K arranged in the Y direction and the element isolation regions I arranged in the Y direction each being sandwiched by the active regions K. The number of the gate electrode trenches 2a that pass through one active region K is two (first and second gate electrode trenches). An inner surface of each of the gate electrode trenches 2a is covered by the gate insulation film 8, and each of the word lines WL is constituted by a conductive film embedded in the gate electrode trench 2a via the gate insulation film 8. Therefore, the number of the word lines WL that pass through one active region K is two (first and second gate electrodes). It is preferable that the conductive film constituting the word line WL is a multilayer film of a titanium nitride film and a tungsten film. In an upper portion of each of the gate electrode trenches 2a, a cap insulation film 9 is embedded to cover an upper surface of the word line WL, by which an insulation is secured between the word line WL and a wiring on an upper layer (such as the bit line BL). An upper surface of the cap insulation film 9 is at the same height as an upper surface of the element isolation region I.

A region between two word lines WL in the active region K of the semiconductor substrate 2 constitutes a bit-line contact region 6. An impurity diffusion layer 12 (first impurity diffusion layer) is provided in an upper portion of the bit-line contact region 6. The impurity diffusion layer 12 constitutes one of controlled electrodes (one of a source and a drain) of each of the corresponding two cell transistors. Furthermore, in the active region K of the semiconductor substrate 2, regions on both sides of the two word lines WL respectively constitute capacitive contact regions 7. Impurity diffusion layers 21a and 21b (second and third impurity diffusion layers) are respectively provided in upper portions of the capacitive contact regions 7. The impurity diffusion layers 21a and 21b constitute the other one of the controlled electrodes (the other one of the source and the drain) of the corresponding cell transistor.

An inter-layer insulation film 10 is formed on the upper surface of the semiconductor substrate 2. The inter-layer insulation film 10 includes a bit-line contact hole 11 that is configured to expose the impurity diffusion layer 12 at a bottom of the bit-line contact hole 11, and the bit line BL is constituted by a conductive film that is formed in and above the bit-line contact hole 11. It is preferable that, specifically, this conductive film is a multilayer film of a polysilicon film and a tungsten film. A bottom surface of the bit line BL is electrically connected to the impurity diffusion layer 12. Meanwhile, an insulation film 15 constituted by a silicon nitride film is formed on an upper surface of the bit line BL. A liner film 16 is formed on a side surface of a multilayer film constituted by the bit line BL and the insulation film 15, as shown in FIG. 2. The liner film 16 is also formed on an upper surface of the inter-layer insulation film 10. An SOD (spin on dielectric) film 17 is formed on an upper surface of the liner film 16. An upper surface of the SOD film 17 is at the same height as an upper surface of the insulation film 15.

A capacitive contact hole 20 that passes through the inter-layer insulation film 10, the liner film 16, and the SOD film 17 is provided above each of the impurity diffusion layers 21a and 21b. A conductive film of tungsten or the like is embedded inside the capacitive contact hole 20, and the capacitive contact hole 20 constitutes each of capacitive contact plugs 22a and 22b. Bottom surfaces of the capacitive contact plugs 22a and 22b are electrically connected to the impurity diffusion layers 21a and 21b, respectively.

A capacitive contact pad 30 is provided on an upper surface of each of the capacitive contact plugs 22a and 22b. Furthermore, a stopper film 31 having a thickness to cover the whole capacitive contact pads 30 is provided on an upper layer of the SOD film 17.

On an upper layer of the stopper film 31, two cell capacitors C (first and second capacitors C1 and C2) are arranged for each of the active regions K. As shown in FIG. 2, each of the cell capacitors C is constituted by a lower electrode 33, a capacitive insulation film 34, and an upper electrode 35. The lower electrode 33 is a conductive film having a three-dimensional cylindrical shape, and a lower portion of the lower electrode 33 is brought into contact with an upper surface of the corresponding capacitive contact pad 30 through the stopper film 31. Further, an upper portion of the lower electrode 33 is connected to an upper portion of an adjacent lower electrode 33 with a support film 32. The capacitive insulation film 34 is formed to cover a portion of a surface of the lower electrode 33 above the stopper film 31 and the support film 32. The upper electrode 35 is a conductive film that is constituted by a multilayer film of polysilicon and tungsten, which covers surfaces of the lower electrode 33 and the support film 32 via the capacitive insulation film 34. An upper surface of the upper electrode 35 is higher than an upper surface of the support film 32.

On the upper surface of the upper electrode 35, a wiring 37 that is constituted by a conductive film of aluminum or the like is arranged. Further, the upper surface of the upper electrode 35 is covered with an inter-layer insulation film 38 having a thickness to cover the whole wiring 37, and a surface protection film 39 is formed on an upper surface of the inter-layer insulation film 38.

The well 3 mentioned above is explained next in detail with reference to a prototype example.

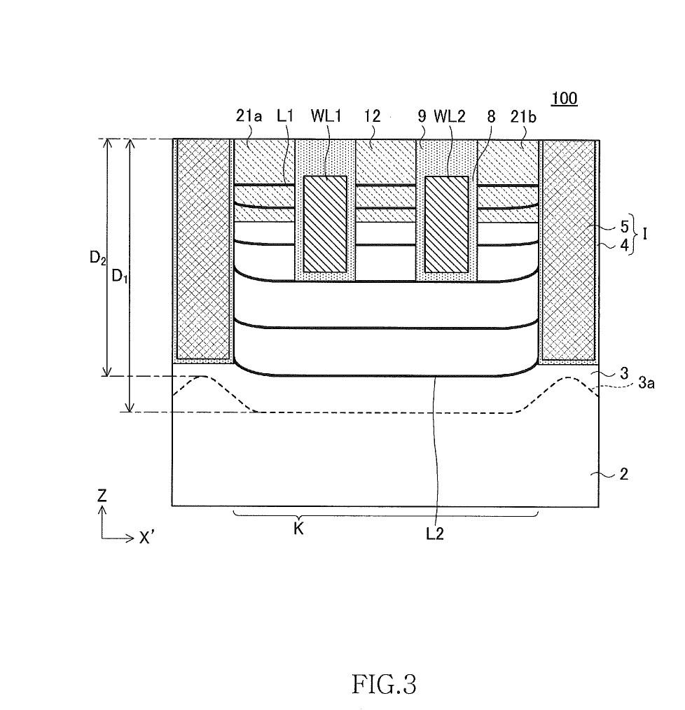

Turning to FIGS. 3 to 6, a semiconductor device 100 according to the prototype example of the present invention has the same structure as that of the semiconductor device 1 according to the present embodiment except that the density distribution of the impurity in the well 3 is different. Therefore, a plan view of the semiconductor device 100 is the same as that of the semiconductor device 1 shown in FIG. 1. FIGS. 3 to 6 are cross-sectional views of the semiconductor device 100 corresponding to a cross section cut along a line A-A shown in FIG. 1. In FIGS. 3 to 6, the portion above the surface of the semiconductor substrate 2 is omitted from the drawing. Note that the semiconductor device 100 is only a prototype example and it is not a prior art.

Lines L1 and L2 shown in FIGS. 3, 5, and 6 indicate edge portions of a depletion layer generated at junction portions of the well 3 and the impurity diffusion layers 12, 21a, and 21b. A region above the line L1 is a neutral region of n-type, and a region below the line L2 is a neutral region of p-type. Thick lines between the lines L1 and L2 schematically represent potential distributions in the depletion layer.

FIG. 3 shows a potential distribution with a zero bias (both the word line WL1 and the word line WL2 are deactivated and both the cell capacitor C1 and the cell capacitor C2 maintain 0 V). As shown in FIG. 3, in the semiconductor device 100, the peak depth D₁ in the active region K is larger than the peak depth D₂ in the element isolation region I. As a result, as shown in FIG. 3, the potential distribution in the depletion layer is shrunk toward an upper side (in a direction approaching the surface of the semiconductor substrate) particularly near the element isolation region I.

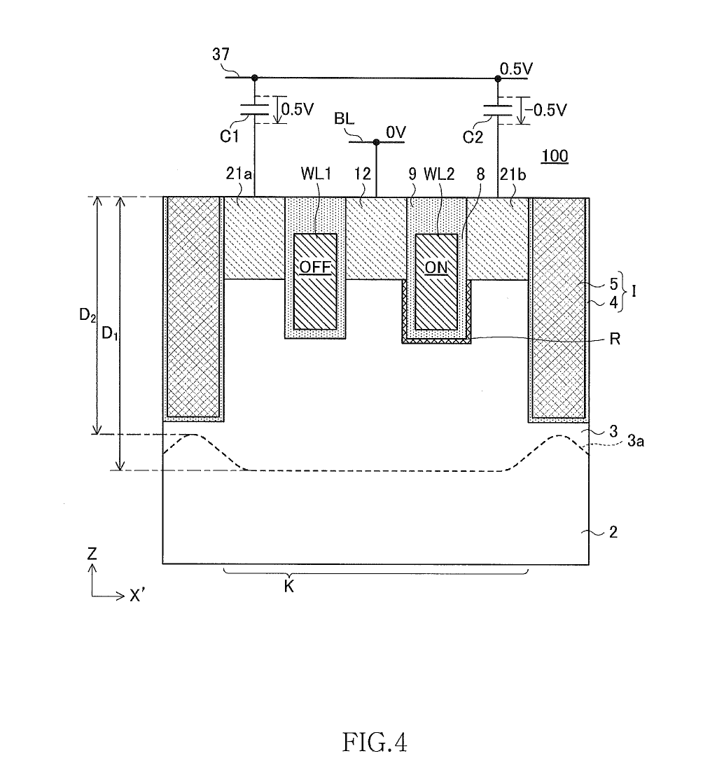

In the semiconductor device 100 described above, when the cell capacitor C1 maintains 0.5 V (a high level), if −0.5 V (a low level) is written in the cell capacitor C2, the potential of the bit line BL is set to 0 V and the word line WL2 is activated, as shown in FIG. 4. When the word line WL2 is in an activated state (an ON state), an inversion layer R is formed in a region (a channel region of a cell transistor having the word line WL2 as the gate electrode) near the word line WL2 in the well 3, as shown in FIG. 4. This electrically connects the impurity diffusion layer 12 and the impurity diffusion layer 21b, and then the potential of the lower electrode 33 (see FIG. 2) of the cell capacitor C2 becomes equal to the potential of the bit line BL, which is 0 V. That is, the potential of −0.5 V is written in the cell capacitor C2.

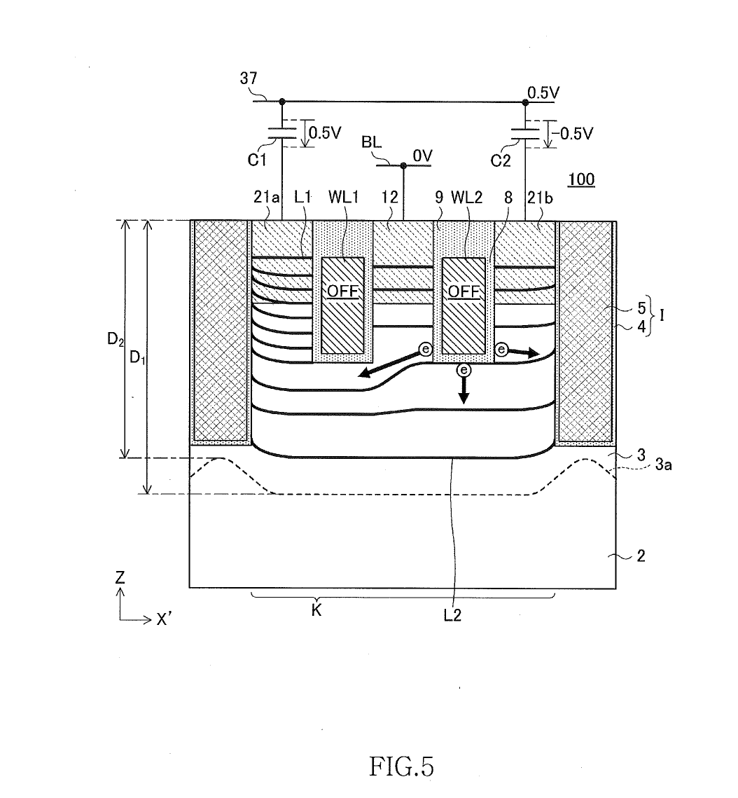

After completion of the writing, when the word line WL2 is returned to a deactivated state (an OFF state), the inversion layer R is extinguished. However, a part of electrons existed in the inversion layer R repels a deactivation potential of the word line WL2, and as shown in FIG. 5, starts to move in a direction separating from the word line WL2. The direction of movement of the electrons at this time is random in the well 3. Therefore, a part of the electrons moves toward the word line WL1.

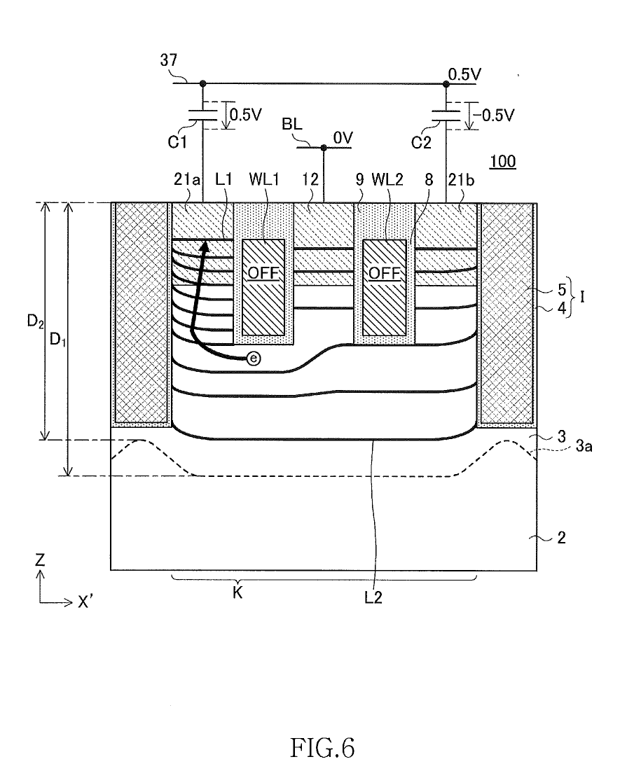

Most of the electrons moved toward the word line WL1 are trapped by the interface state between the element isolation region I and the well 3, and then extinguished. However, some of the electrons pass through the impurity diffusion layer 21a and reach the lower electrode 33 (FIG. 2) of the cell capacitor C1 without being trapped by the interface state, as shown in FIG. 6. Such electrons neutralize charges accumulated in the cell capacitor C1, and thus when the number of electrons reaching the lower electrode 33 of the cell capacitor C1 is increased by a repetition of switching on and off the word line WL2, the maintained level of the data of the cell capacitor C1 is eventually destroyed. This is the “disturbance defect” described above.

In this prototype example, as described above, the potential distribution in the depletion layer is shrunk toward an upper side particularly near the element isolation region I. The electron is likely to move along an inclination of the potential, and thus such a potential distribution induces the electron toward the impurity diffusion layer 21a. As a result, in the semiconductor device 100 according to the prototype example, the probability of generating the disturbance defect is increased.

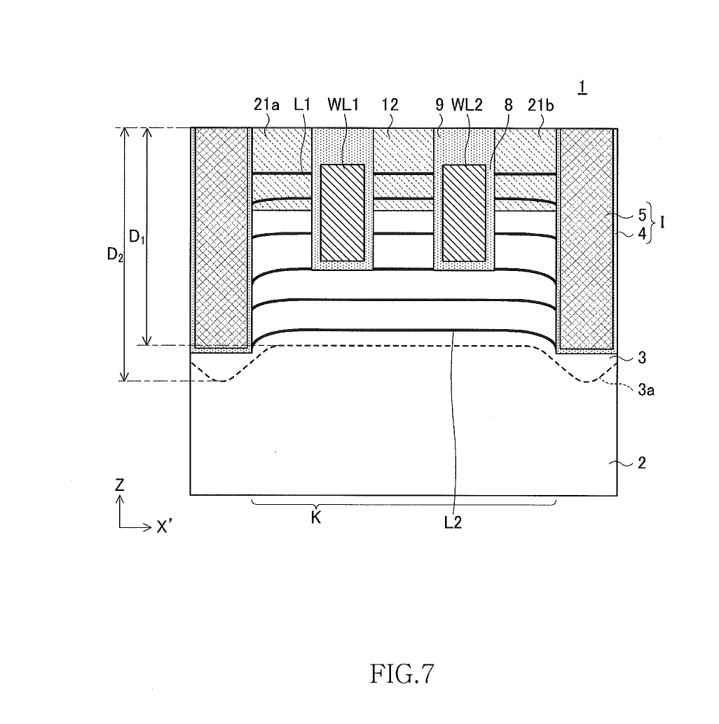

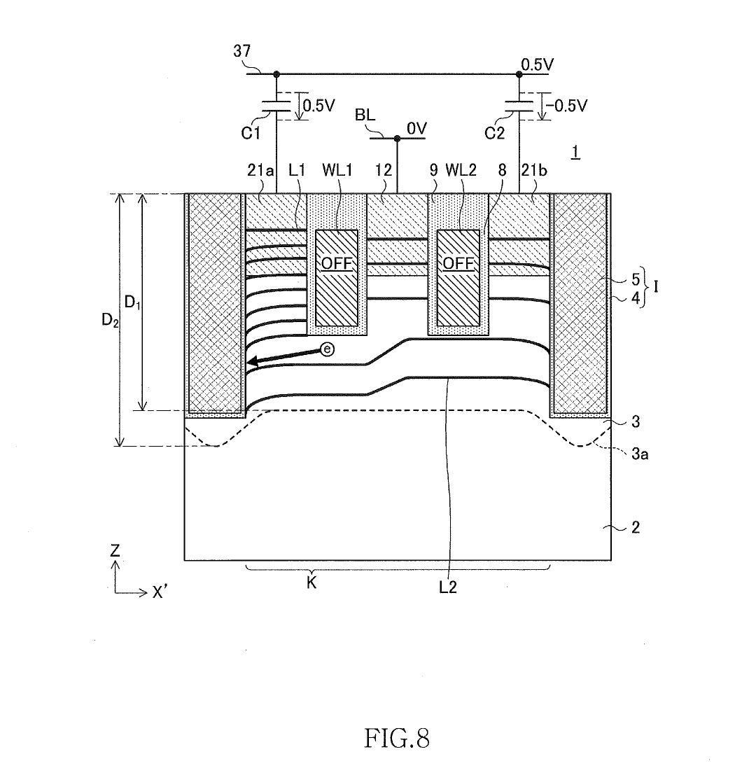

In contrast to the semiconductor device 100 described above, in the semiconductor device 1 according to the present embodiment, by devising the density distribution of the well 3, the probability of generating the disturbance defect is reduced. This aspect is explained below in detail with reference to FIGS. 7 and 8. Also in FIGS. 7 and 8, the portion above the surface of the semiconductor substrate 2 is omitted from the drawings. In addition, meanings of lines L1 and L2 and thick lines between the lines L1 and L2 shown in FIGS. 7 and 8 are the same as those of the lines shown in FIG. 3 and the like.

As shown in FIG. 7, in the semiconductor device 1, the potential distribution in the depletion layer is spread toward a lower side particularly near the element isolation region I. For this reason, when electrons are generated, which move toward the word line WL1 from the word line WL2 in the same manner as the example shown in FIGS. 4 to 6, the probability that the electrons are trapped by the interface state between the element isolation region I and the well 3 is increased (see FIG. 8), as compared to the case of the semiconductor device 100. As a result, the number of electrons that pass through the impurity diffusion layer 21a and reach the lower electrode 33 (see FIG. 2) of the cell capacitor C1 is decreased, and thus, in the semiconductor device 1, the probability of generating the disturbance defect is reduced, as compared to the case of the semiconductor device 100.

As explained above, with the semiconductor device 1 according to the present embodiment, the potential distribution in the depletion layer generated at the junction portions of the well 3 of the p-type and the impurity diffusion layers 12, 21a, and 21b of the n-type is spread toward a lower side (in a direction separating from the surface of the semiconductor substrate 2) particularly near the element isolation region I, and thus the electrons generated by switching on and off the word lines WL1 and WL2 are likely to be trapped by the interface state between the element isolation region I and the well 3. Therefore, as compared to the semiconductor device 100 according to the prototype example, the probability that the electrons reach the lower electrode 33 of the cell capacitors C1 and C2 is reduced, and the generation of the disturbance defect is eventually suppressed.

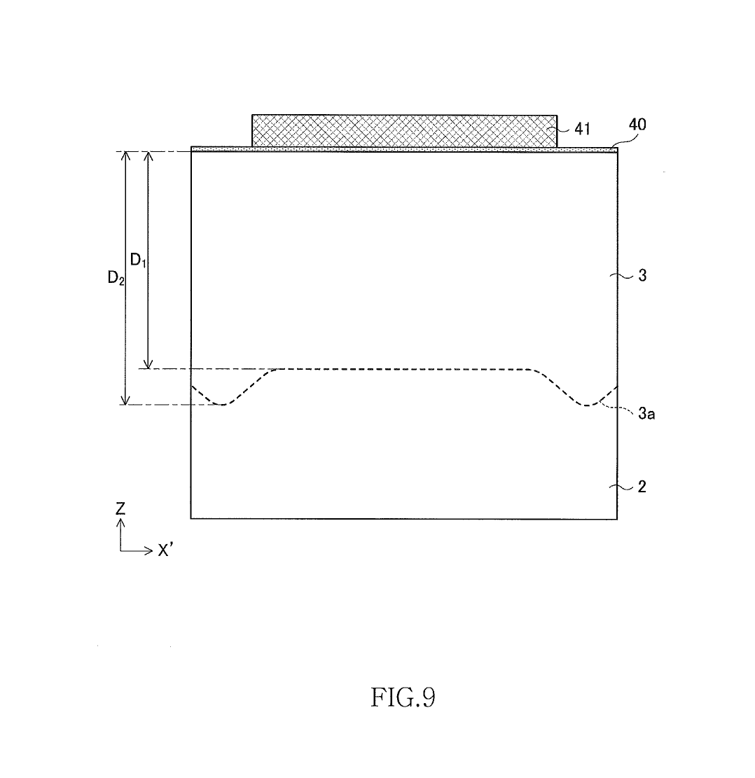

A manufacturing method of the semiconductor device 1 that includes the well 3 described above is explained below with reference to FIGS. 9 to 11. FIGS. 9 to 11 are cross-sectional views of the semiconductor device 1 corresponding to the line A-A shown in FIG. 1 during manufacturing thereof.

First, a silicon oxide film 40 with a thickness of 10 nm and a silicon nitride film 41 with a thickness of 40 nm are sequentially deposited on the surface of the semiconductor substrate 2. Subsequently, as shown in FIG. 9, a portion of the silicon nitride film 41 formed in a region (first region) that corresponds to the element isolation region I is removed. Other portions of the silicon nitride film 41 are left as they are. In other words, only the silicon nitride film 41 is patterned to be a pattern of the active region K. In this state, Boron of 5*10¹³/cm² is implanted in the surface of the semiconductor substrate 2 with energy of 120 keV, by which the well 3 of the p-type is formed. A depth (a peak depth) of the peak line 3a of Boron implanted in this manner becomes relatively shallow in the active region K and relatively deep in the element isolation region I, as shown in FIG. 9, because the active region K is covered with the silicon nitride film at the time of implanting Boron. Specifically, it is preferable that the peak depth D₂ of the well 3 in the element isolation region I is set to be equal to or larger than the peak depth D₁ of the well 3 in the active region K and equal to or smaller than 1.2 times the peak depth D₁, and more preferably set to be 1.17 times the peak depth D₁. The lower limit of the peak depth D₂, that is, equal to or larger than the peak depth D₁, is determined according to an aspect of suppressing the generation of the disturbance defect, and the upper limit (1.2 times) is determined according to an aspect of assuring an element isolation capability of the element isolation region I. However, in some cases, the upper limit may be preferable to be smaller than 1.2 times the peak depth D₁ depending on the width of the element isolation region I. The ratio of 1.17 can be achieved by, for example, setting the peak depth D₂ to 340 nm and the peak depth D₁ to 290 nm. Specific values of the peak depths D₁ and D₂ can be adjusted by adjusting the energy of implanting Boron or the thickness of the silicon nitride film 41.

In the manufacturing method of the semiconductor device 1, it is more important to perform the implantation of Boron before forming the element isolation region I than to form the silicon nitride film 41. As this process enables Boron to be implanted without being blocked by the element isolation region I, the peak depth D₂ of the well 3 in the element isolation region I can be formed deeper than the peak depth D₁ of the well 3 in the active region K. When the implantation of Boron is performed with energy of 100 keV, for example, without forming the silicon nitride film 41, the peak depth D₂ and the peak depth D₁ can be formed equal to each other (a uniform peak depth can be obtained).

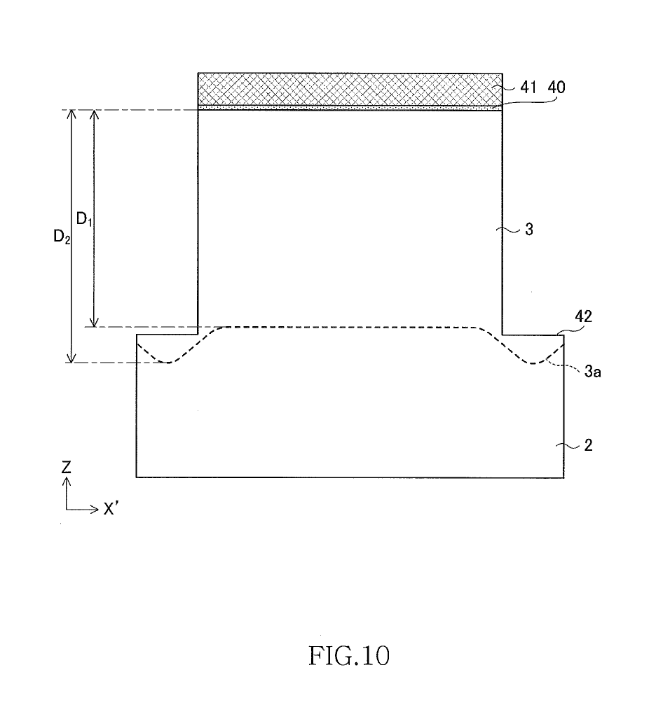

Subsequently, as shown in FIG. 10, an element isolation trench 42 is formed by removing the silicon oxide film 40 and the semiconductor substrate 2 (the well 3) by dry etching using the silicon nitride film 41 as a mask.

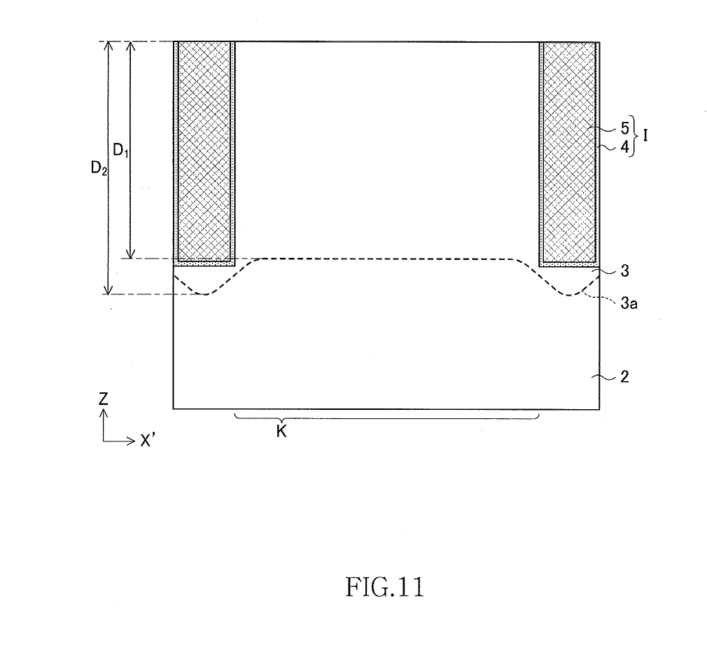

Thereafter, the element isolation region I is embedded in the element isolation trench 42 formed in the above manner, as shown in FIG. 11. Specifically, the silicon oxide film 4 that covers an inner surface of the element isolation trench 42 is formed, and then the silicon nitride film 5 that fills in the element isolation trench 42 is formed. Planarization is then performed by a CMP method to remove a portion of the silicon nitride film 5 formed on the surface of the semiconductor substrate 2 and the silicon nitride film 41. At this stage, a portion of the silicon oxide film 4 formed on an upper surface of the silicon nitride film 41 is also removed. Furthermore, by removing the silicon oxide film 40, the element isolation region I embedded in the element isolation trench 42 is completed, and the surface of the semiconductor substrate 2 is exposed in the active region K. The word line WL, the bit line BL, the memory cell and the like are then formed to complete the semiconductor device 1 shown in FIGS. 1 and 2.

As explained above, with the manufacturing method of the semiconductor device 1 according to the present embodiment, the semiconductor device 1 having the well 3, in which the peak depth is relatively shallow in the active region K and relatively deep in the element isolation region I, can be manufactured.

It is apparent that the present invention is not limited to the above embodiments, but may be modified and changed without departing from the scope and spirit of the invention.

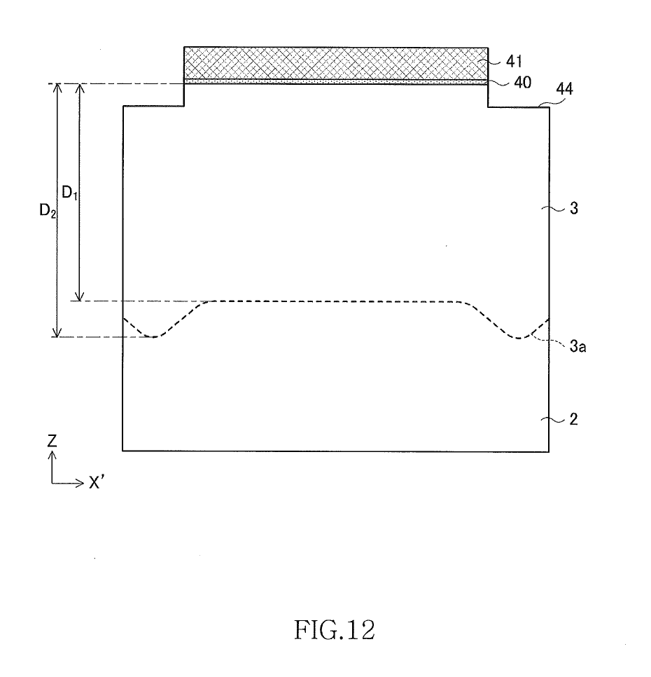

For example, in the above embodiment, the semiconductor substrate 2 is not etched before implanting Boron. However, as shown in FIG. 12, a region to be the element isolation region I is etched before implanting Boron, so that the implantation of Boron can be performed after forming a provisional trench 44, which is shallower than the element isolation trench 42. In this case, the specific value of the peak depth of the well 3 in the element isolation region I can be adjusted by adjusting the depth of the provisional trench 44, and thus it is possible to make the peak depth of the well 3 in the active region K and the peak depth of the well 3 in the element isolation region I differ from each other without necessarily forming the silicon nitride film 41.

In the above embodiment, the element isolation region I is constituted by the silicon oxide film 4 and the silicon nitride film 5. However, instead of the silicon nitride film 5, a silicon oxide film formed by an FCVD (Flowable Chemical Vapor Deposition) method described in U.S. Pat. No. 7,989,365 (hereinafter, “FCVD film”) can be used. In this case, only the silicon oxide film exists in the element isolation trench 42 without any silicon nitride film.

In this context, the passability of ion when implanting it in a thin film or a semiconductor substrate depends on the implantation target material. Specifically, the silicon oxide film is easier for the ion to pass through than the semiconductor substrate, and the semiconductor substrate is easier for the ion to pass through than the silicon nitride film. Therefore, when the element isolation region I is constituted only by the silicon oxide film as described above, the well 3 can be obtained, in which the peak depth is relatively shallow in the active region K and relatively deep in the element isolation region I, by performing the ion implantation after forming the element isolation region I. That is, because the silicon oxide film inside the element isolation region I is easier for the ion to pass through than the semiconductor substrate 2 in the active region K, the ion reaches a deeper position below the element isolation region I, and the peak line 3a shown in FIG. 11 can be obtained.

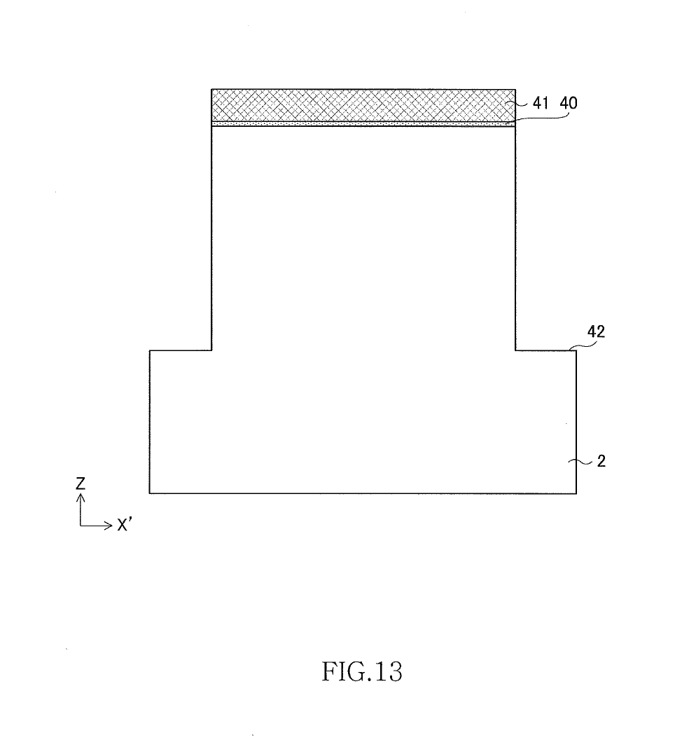

A manufacturing method of the semiconductor device 1 in a case of constituting the element isolation region I with the silicon oxide film 4 and the FCVD film is explained below in detail with reference to FIGS. 13 to 15.

First, in the same manner as the processes described above, the silicon oxide film 40 and the silicon nitride film 41 are sequentially deposited on the surface of the semiconductor substrate 2. Patterning along the pattern of the active region K is then performed, and by performing dry etching using the silicon nitride film 41 as a mask, the element isolation trench 42 is formed as shown in FIG. 13 Unlike the embodiment described above, the well 3 is not formed at this stage.

Subsequently, in the same manner as the processes shown in FIG. 11, as shown in

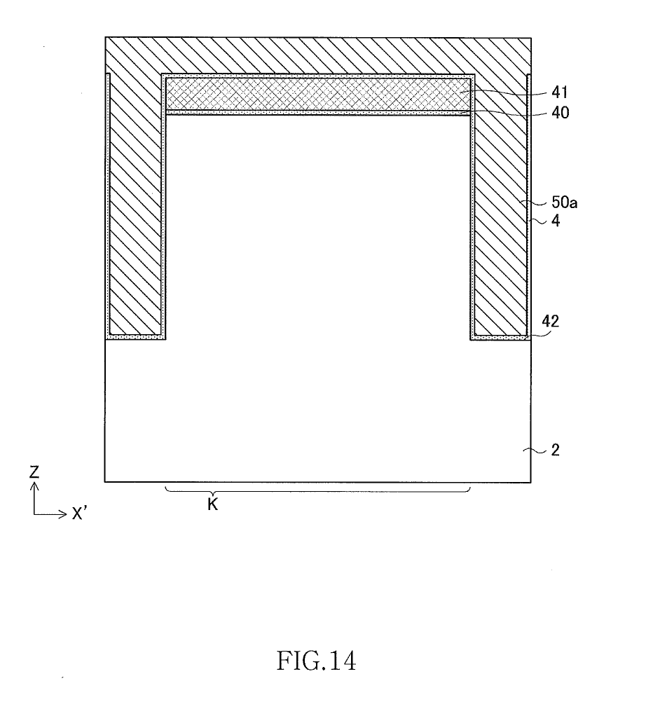

FIG. 14, a thin layer of the silicon oxide film 4 is formed on the entire surface. Thereafter, an FCVD film 50a (silicon oxide film) with a thickness to fill inside the element isolation trench 42 is deposited by using the FCVD method.

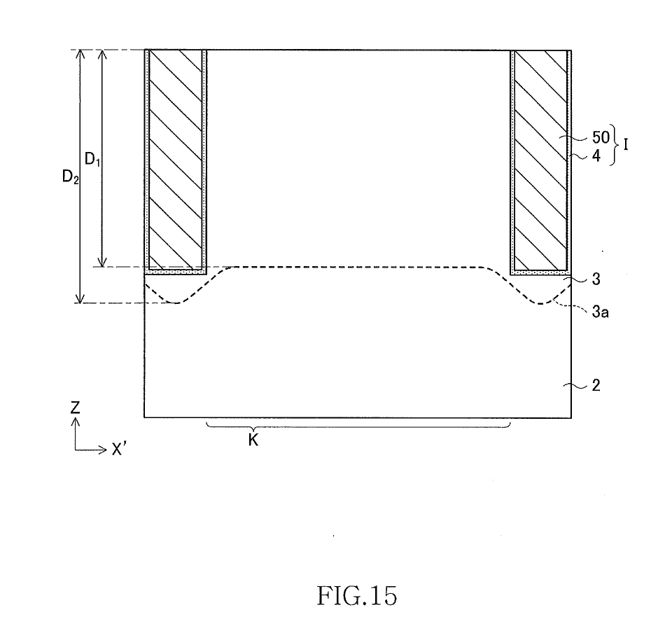

Thereafter, the FCVD film 50a is modified by performing annealing. It is preferable that the annealing is performed in a nitride (N₂) atmosphere at a temperature ranging from 400?C to 1000?C. An FCVD film 50 (see FIG. 15) obtained by the modification is then planarized by using the CMP method until the surface of the semiconductor substrate 2 is exposed. This planarization also removes portions of the silicon nitride film 41, the silicon oxide film 40, and the silicon oxide film 4 formed above the surface of the semiconductor substrate 2, and as shown in FIG. 15, the element isolation region I constituted by the silicon oxide film 4 and the FCVD film 50 is formed in the element isolation trench 42.

Subsequently, Boron of 5*10¹³/cm² is implanted in the entire surface with energy of 100 keV, by which the well 3 of the p-type is formed, as shown in FIG. 15. At this time, as described above, because the silicon oxide film (the silicon oxide film 4 and the FCVD film 50) is easier for the ion to pass through than the semiconductor substrate 2, the peak depth D₂ of the well 3 in the element isolation region I becomes larger than the peak depth D₁ of the well 3 in the active region K, as shown in FIG. 15. That is, the well 3, in which the peak depth is relatively shallow in the active region K and relatively deep in the element isolation region I, can be obtained. Processes thereafter are identical to those of the embodiment described above.

In this manner, when the element isolation region I is constituted by the silicon oxide film 4 and the FCVD film 50, by performing ion implantation after forming the element isolation region I, it is possible to obtain the well 3, in which the peak depth is relative shallow in the active region K and relatively deep in the element isolation region I.

In addition, while the above embodiment has explained a case where the well 3 is the p-type and the impurity diffusion layers 12, 21a, and 21b are the n-type, it is also permitted that the well 3 is the n-type and the impurity diffusion layers 12, 21a, and 21b are the p-type. That is, it suffices that, when the well 3 is a first conductive type, the impurity diffusion layers 12, 21a, and 21b are a second conductive type that is different from the first conductive type.

1. A semiconductor device comprising:
a semiconductor substrate having a main surface;
a well of a first conductive type formed in the semiconductor substrate;
an element isolation region embedded in the semiconductor substrate so as to define an active region of the semiconductor substrate;
first and second gate electrodes each embedded in the semiconductor substrate with an intervention of a gate insulation film such that the first and second gate electrodes are formed to traverse the active region, each of the first and second gate electrodes having a top surface that is lower in position than the main surface of the semiconductor substrate;
a first impurity diffusion layer of a second conductive type that is formed between the first gate electrode and the second gate electrode in the active region, the second conductive type being different from the first conductive type; and
a second impurity diffusion layer of the second conductive type that is formed between the first gate electrode and the element isolation region in the active region, and
a peak depth of the well corresponding to the active region is equal to or shallower than a peak depth of the well corresponding to the element isolation region.

2. The semiconductor device as claimed in claim 1, further comprising a first cell capacitor including a lower electrode that is electrically connected to the second impurity diffusion layer.

3. The semiconductor device as claimed in claim 2, further comprising:
a third impurity diffusion layer of the second conductive type that is formed between the second gate electrode and the element isolation region in the active region; and
a second cell capacitor including a lower electrode that is electrically connected to the third impurity diffusion layer.

4. The semiconductor device as claimed in claim 1, wherein the element isolation region includes an insulation film that fills an element isolation trench that is formed in the semiconductor substrate with an intervention of a silicon oxide film.

5. The semiconductor device as claimed in claim 4, wherein the insulation film comprises at least one of a silicon nitride film and a silicon oxide film.

6. The semiconductor device as claimed in claim 1, further comprising a bit line that is electrically connected to the first impurity diffusion layer,
wherein the first and second gate electrodes work as first and second word lines, respectively.

7. A semiconductor device comprising:
a semiconductor substrate;
a well of a first conductive type that is formed in the semiconductor substrate;
an element isolation region that is embedded in the semiconductor substrate so as to define a plurality of active regions of the semiconductor substrate arranged along a first direction; and
first and second word lines that are embedded in the semiconductor substrate with an intervention of a gate insulation film and extend along the first direction across the active regions, where an uppermost surface of each of the first and second word lines are lower than an uppermost surface of the semiconductor substrate, and each of the active regions includes:
a first impurity diffusion layer of a second conductive type that is formed between the first word line and the second word line, where the second conductive type is different from the first conductive type; and
a second impurity diffusion layer of the second conductive type that is formed between the first word line and the element isolation region, and
a peak depth of the well corresponding to each of the active regions is equal to or shallower than a peak depth of the well corresponding to the element isolation region.

8. The semiconductor device as claimed in claim 7, wherein each of the active regions includes a first cell capacitor that includes a lower electrode connected to the second impurity diffusion layer.

9. The semiconductor device as claimed in claim 8, wherein each of the active regions further includes:
a third impurity diffusion layer of the second conductive type that is formed between the second word line and the element isolation region; and
a second cell capacitor that includes a lower electrode electrically connected to the third impurity diffusion layer.

10. The semiconductor device as claimed in claim 7, wherein the element isolation region includes an insulation film that fills an element isolation trench that is formed in the semiconductor substrate with an intervention of a silicon oxide film.

11. The semiconductor device as claimed in claim 7, further comprising a plurality of bit lines each electrically connected to the first impurity diffusion layer in an associated one of the active regions.

12. A semiconductor device, comprising:
a semiconductor substrate having a main surface;
a well of a first conductive type that is formed in the semiconductor substrate;
an element isolation region embedded in the semiconductor substrate so as to define an active region of the well;
first and second gate electrodes each including a top surface, a side surface and a bottom surface, the side and bottom surfaces of each of the first and second gate electrodes being covered with the well such that the first and second gate electrodes are formed to traverse the active region, the top surface of each of the first and second gate electrodes being lower in position than the main surface of the semiconductor substrate, and
a peak depth of the well corresponding to the active region is equal to or shallower than a peak depth of the well corresponding to the element isolation region.

13. The semiconductor device as claimed in claim 12, further comprising:
a first impurity diffusion layer of a second conductive type that is formed between the first gate electrode and the second gate electrode in the active region, the second conductive type being different from the first conductive type; and
a second impurity diffusion layer of the second conductive type that is formed between the first gate electrode and the element isolation region in the active region.

14. The semiconductor device as claimed in claim 12, wherein
the side surface and bottom surface of the first and second gate electrodes are covered with the well with an intervention of a gate oxide film, and
each of the first and second gate electrodes further includes a top surface that is covered with a cap insulation film that is embedded in the well.

15. The semiconductor device as claimed in claim 14, wherein uppermost surfaces of the element isolation region and the cap insulation film are substantially coplanar with an uppermost surface of the semiconductor substrate.

16. The semiconductor device as claimed in claim 13, further comprising a first cell capacitor including a lower electrode that is electrically connected to the second impurity diffusion layer.

17. The semiconductor device as claimed in claim 16, further comprising:
a third impurity diffusion layer of the second conductive type that is formed between the second gate electrode and the element isolation region in the active region; and
a second cell capacitor that including a lower electrode that is electrically connected to the third impurity diffusion layer.

18. The semiconductor device as claimed in claim 12, wherein the element isolation region includes an insulation film that fills an element isolation trench that is formed in the semiconductor substrate with an intervention of a silicon oxide film.

19. The semiconductor device as claimed in claim 18, wherein the insulation film comprises at least one of a silicon nitride film and a silicon oxide film.

20. The semiconductor device as claimed in claim 13, further comprising a bit line that is electrically connected to the first impurity diffusion layer,
wherein the first and second gate electrodes work as first and second word lines, respectively.

21. A manufacturing method of a semiconductor device, the method comprising:
etching a semiconductor substrate to form an element isolation trench;
filling the element isolation trench with an insulation film to form an element isolation region that defines an active region in the semiconductor substrate;
implanting an impurity into the semiconductor substrate to form a well of a first conductive type such that a peak depth of the well corresponding to the active region is equal to or shallower than a peak depth of the well corresponding to the element isolation region;
forming first and second gate electrode trenches so as to stride across the active region; and
embedding a conductive material in each of the first and second gate electrode trenches, the conductive material having an upper surface that is lower than an uppermost surface of the semiconductor substrate.

22. The manufacturing method of a semiconductor device as claimed in claim 21, wherein the etching, filling, and implanting are performed in this order.

23. The manufacturing method of a semiconductor device as claimed in claim 22, wherein
the insulation film comprises a silicon oxide film, and
the silicon oxide film is formed by depositing using an FCVD (Flowable Chemical Vapor Deposition) apparatus and annealing.

24. The manufacturing method of a semiconductor device as claimed in claim 21, wherein the implanting, etching and filling are performed in this order.

25. The manufacturing method of a semiconductor device as claimed in claim 24, wherein the insulation film comprises a first silicon nitride film.

26. The manufacturing method of a semiconductor device as claimed in claim 25, further comprising:
forming a second silicon nitride film on the semiconductor substrate; and
selectively removing a part of the second silicon nitride film that corresponds to the element isolation region,
wherein the implanting is performed after the selectively removing.

27. The manufacturing method of a semiconductor device as claimed in claim 26, wherein the implanting is performed after a part of the semiconductor substrate corresponds to the element isolation region is etched.

28. The manufacturing method of a semiconductor device as claimed in claim 21, wherein the impurity comprises Boron.

29. The manufacturing method of a semiconductor device as claimed in claim 21, further comprising:
forming a first impurity diffusion layer of a second conductive type between the first and second gate electrode trenches in the active region, the second conductive type being different from the first conductive type; and
forming a second impurity diffusion layer of the second conductive type between the first gate electrode trench and the element isolation region in the active region.

30. The manufacturing method of a semiconductor device as claimed in claim 29, further comprising forming a cell capacitor that includes a lower electrode electrically connected to the second impurity diffusion layer.

31. A manufacturing method of a semiconductor device, the method comprising:
etching a semiconductor substrate to form an element isolation trench;
filling the element isolation trench with an insulation film to form an element isolation region that defines a plurality of active regions of the semiconductor substrate, the active regions being arranged in a first direction;
implanting an impurity into the semiconductor substrate to form a well of a first conductive type such that a peak depth of the well corresponding to the active regions is equal to or shallower than a peak depth of the well corresponding to the element isolation region; and
forming first and second embedded gate electrodes that are embedded in the semiconductor substrate, the first and second embedded gate electrodes extending in the first direction so as to stride across the active regions, the first and second embedded gate electrodes having an upper surface that is lower than an uppermost surface of the semiconductor substrate.

32. The manufacturing method of a semiconductor device as claimed in claim 31, wherein the etching, filling, and implanting are performed in this order.

33. The manufacturing method of a semiconductor device as claimed in claim 31, wherein the insulation film comprises a silicon oxide film that are formed by depositing using an FCVD (Flowable Chemical Vapor Deposition) apparatus and annealing.

34. The manufacturing method of a semiconductor device as claimed in claim 31, wherein the implanting, etching and filling are performed in this order.

35. The manufacturing method of a semiconductor device as claimed in claim 34, wherein the insulation film comprises a first silicon nitride film.

36. The manufacturing method of a semiconductor device as claimed in claim 35, further comprising:
forming a second silicon nitride film on the semiconductor substrate; and
selectively removing a part of the second silicon nitride film that corresponds to the element isolation region,
wherein the implanting is performed after the selectively removing.

37. The manufacturing method of a semiconductor device as claimed in claim 36, wherein the implanting is performed after a part of the semiconductor substrate corresponds to the element isolation region is etched.

38. The manufacturing method of a semiconductor device as claimed in claim 31, wherein the impurity comprises Boron.

39. The manufacturing method of a semiconductor device as claimed in claim 31, further comprising:
forming a first impurity diffusion layer of a second conductive type between the first and second embedded gate electrodes in the active region, the second conductive type being different from the first conductive type; and
forming a second impurity diffusion layer of the second conductive type between the first gate electrode trench and the element isolation region in the active region.

40. The manufacturing method of a semiconductor device as claimed in claim 39, further comprising forming a cell capacitor that includes a lower electrode electrically connected to the second impurity diffusion layer.
